(19) United States
(12) Patent Application Publication
(10) Pub. No.: US 2025/0008819 A1
(43) Pub. Date: Jan. 2, 2025

(54) DISPLAY APPARATUS AND METHOD OF FABRICATING THEREOF

(71) Applicant: LG Display Co., Ltd., Seoul (KR)

(72) Inventors: Dae-Hee KIM, Paju-si (KR); Moon-Soo KIM, Paju-si (KR)

(73) Assignee: LG Display Co., Ltd., Seoul (KR)

(21) Appl. No.: 18/756,992

(22) Filed: Jun. 27, 2024

(30) Foreign Application Priority Data
Jun. 28, 2023 (KR) 10-2023-0083504

(51) Int. Cl. H10K 59/80; H10K 59/12

(52) U.S. Cl. CPC H10K 59/873; H10K 59/1201; H10K 59/80522

(57) ABSTRACT

A display apparatus can include a substrate having a plurality of sub-pixels and a contact unit. The display apparatus further includes at least one transistor disposed in each sub-pixel, a light emitting device disposed in each sub-pixel and having a first electrode, an organic layer, and a second electrode, an auxiliary electrode disposed in the contact unit to supply a voltage to the light emitting device, and a blocking layer disposed on the auxiliary electrode to block moisture from outside. The blocking layer includes a first pattern made of an orthogonal material and a second pattern on the first pattern. A width of the blocking layer is smaller than a width of the auxiliary electrode so that the auxiliary electrode is extended to outside of at least one side of the blocking layer and the auxiliary electrode is exposed to the outside.

### CROSS-REFERENCE TO RELATED APPLICATIONS

This application claims priority to Korean Patent Application No. 10-2023-0083504, filed in the Republic of Korea on Jun. 28, 2023, the entire contents of which is hereby expressly incorporated by reference into the present application.

### BACKGROUND

### Field

This disclosure relates to a display apparatus and a fabricating method of preventing lateral leakage current and moisture penetration.

### Discussion of the Related Art

As information technology develops, various types of small and thin display apparatus such as a Liquid Crystal Display Device, an Organic Light Emitting Display Device, a Plasma Display Device, a Micro LED Display Device, etc., are proposed. These display apparatuses are applied to various electronic devices such as smart phones and tablet PCs.

Inside the display apparatus, a display element including an organic light emitting layer and various electrodes are formed. In this display apparatus, there was a problem that when moisture from the outside penetrated into the display apparatus, the electrodes were corroded and the organic light emitting layer was deteriorated.

In addition, recently, high-resolution display apparatus is manufactured by minimizing the distance between sub-pixels. However, in this case, as the distance between adjacent sub-pixels decreases, the lateral leakage current flows between adjacent sub-pixels, and this lateral leakage current causes unwanted light emission from the sub-pixels.

### SUMMARY OF THE DISCLOSURE

An object of the present disclosure is to provide a display apparatus and manufacturing method that can prevent a lateral leakage current and moisture infiltration.

Another object of the present disclosure is to provide the display apparatus and manufacturing method that can simplify the manufacturing process.

A display apparatus according to an example of the present disclosure comprises a substrate including a plurality of sub-pixel and a contact unit; at least one transistor disposed in each sub-pixel; a light emitting device disposed in each sub-pixel, the light emitting device including a first electrode, an organic layer, and a second electrode; an auxiliary electrode disposed in the contact unit to supply a voltage to the light emitting device; and a blocking layer over the auxiliary electrode to block moisture from outside, wherein the blocking layer including a first pattern made of an orthogonal material and a second pattern on the first pattern, wherein a width of the blocking layer is smaller than that of the auxiliary electrode so that the auxiliary electrode is extended to outside of at least one side of the blocking layer and the auxiliary electrode is exposed to outside, and wherein the second electrode is extended to the blocking layer from the sub-pixel so that the second electrode is formed on both sides of the blocking layer and on the exposed region of the auxiliary electrode.

According to an aspect of the present disclosure, a first pattern is formed of a fluoropolymer material containing a large amount of fluorine (F) in the functional while carbon-carbon bonds are formed continuously in a chain structure. Further, a first pattern has hydrophobicity and oleophobicity. A second pattern is formed of a photoresist.

According to an aspect of the present disclosure, a first insulating layer covers the transistor and a bank layer is disposed between the plurality sub-pixels over the first insulating layer. The transistor includes a semiconductor layer over the substrate; a second insulating layer covering the semiconductor layer; a gate electrode on the second insulating layer; a third insulating layer covering the gate electrode; and a source electrode and a drain electrode on the third insulating layer.

According to an aspect of the present disclosure, an opening that the bank layer and the third insulating layer are removed is formed in the contact unit, and the auxiliary electrode is disposed within the opening. The auxiliary electrode is formed of the same material as the source electrode and the drain electrode.

According to an aspect of the present disclosure, a disconnection unit over the bank layer at one side of the sub-pixel to disconnect the second electrode between the adjacent sub-pixels. The disconnection unit includes a first disconnection layer disposed on the bank layer; and a second disconnection layer on the first disconnect layer, wherein the width of the first disconnect layer is smaller than that of the second disconnect layer so that the disconnect unit is formed in an undercut shape. The first disconnection layer is formed of the fluoropolymer material containing a large amount of fluorine (F) in the functional while carbon-carbon bonds are formed continuously in the chain structure, and the second disconnection layer is formed of the photoresist. The disconnection unit disposed at one side of the sub-pixel includes a plurality of disconnection units.

A method of manufacturing a display apparatus according to an aspect of the present disclosure comprises proving a substrate including a plurality of sub-pixels and a contact unit; forming a transistor in each sub-pixel; forming an auxiliary electrode in the contact unit; forming a first electrode and an organic layer in each sub-pixel; depositing an orthogonal material and a photoresist over entire area of the substrate; developing the photoresist to form a photoresist pattern on the auxiliary electrode in the contact unit; over-etching the orthogonal material by the photoresist pattern to form a blocking layer of an undercut shape; heat-treating the blocking layer; and forming a second electrode over entire area of the substrate, wherein the second electrode is formed on both side and upper surfaces of the blocking layer and is electrically connected to the auxiliary electrode extended from both side surfaces of the blocking layer.

According to an aspect of the present disclosure, an insulating layer is formed to cover the transistor and a bank layer is formed between the sub-pixels over the insulating layer. An opening is formed to etch the insulating layer and the bank layer in the contact unit. the auxiliary electrode is formed within the opening.

According to an aspect of the present disclosure, a disconnection unit is formed over the bank layer. The disconnection unit includes a first connection layer formed of the orthogonal material and a second disconnection layer formed of the photoresist on the first disconnection layer. The connection unit and the blocking layer are simultaneously formed.

According to an aspect of the present disclosure, forming the organic layer includes depositing continuously the orthogonal material and the photoresist over entire area of the substrate; removing the photoresist over the first electrode to form the photoresist pattern; etching the orthogonal material using the photoresist pattern as a mask; depositing an organic material over entire area of the substrate; and forming the organic layer in the plurality of sub-pixel by removing the orthogonal material to remove the photoresist pattern and the organic material over the orthogonal material.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a schematic block diagram of an organic light emitting display apparatus according to an aspect of the present disclosure.

FIG. 2 is the schematic block diagram of a sub-pixel of the organic light emitting display apparatus according to an aspect of the present disclosure.

FIG. 3 is a circuit diagram conceptually showing the sub-pixel of the organic light emitting display apparatus according to an aspect of the present disclosure.

FIG. 4 is a plan view showing a pixel of the display apparatus according to a first embodiment of the present disclosure.

FIGS. 5A-5C are plan views showing other example structures of the pixel of the display apparatus according to the first embodiment of the present disclosure.

FIG. 6 is a cross-sectional view showing the structure of the sub-pixel of the display apparatus according to the first embodiment of the present disclosure.

FIG. 7 is a cross-sectional view showing the structure of the sub-pixel of the display apparatus according to a second embodiment of the present disclosure.

FIGS. 8A and 8B are plan views of the display apparatus according to a third embodiment of the present disclosure.

FIG. 9 is a cross-sectional view of the display apparatus according to the third embodiment of the present disclosure.

FIGS. 10A-10M are views showing a method of manufacturing the display apparatus according to an aspect of the present disclosure.

### DETAILED DESCRIPTION OF THE EMBODIMENTS

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts can be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “over,” “above,” “below,” “under,” “next to,” or the like, unless “immediately” or “directly” is used, one or more other parts can be located between the two parts.

In describing a temporal relationship, for example, when a temporal predecessor relationship is described as being “after,” “subsequent,” “next to,” “prior to,” or the like, unless “immediately” or “directly” is used, cases that are not continuous can also be included.

Although the terms first, second, and the like are used to describe various components, these components are not substantially limited by these terms. These terms are used only to distinguish one component from another component. Therefore, a first component described below can substantially be a second component within the technical spirit of the present disclosure.

In describing the components of the disclosure, terms such as first, second, A, B, (a), (b), etc. can be used. These terms are only for distinguishing the elements from other elements, and the essence, order, or number of the elements are not limited by the terms. When it is described that a component is “coupled” or “connected” to another component, the component can be directly coupled or connected to the other component, but indirectly without specifically stated. It should be understood that other components can be “interposed” between each component that is connected or can be connected.

As used herein, the term “apparatus” can include a display apparatus such as a liquid crystal module (LCM) including a display panel and a driving unit for driving the display panel, and an organic light emitting display module (OLED module). Further, the term “apparatus” can further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure can include the display apparatus itself such as the LCM, the OLED module, etc., and the application product including the LCM, the OLED module, or the like, or the set apparatus, which is the apparatus for end users.

Hereinafter, the disclosure will be described in detail with reference to the accompanying drawings.

This disclosure can be applied to the various display apparatus. For example, the display apparatus of this disclosure can be applied to various display apparatus such as an organic light emitting display apparatus, a liquid crystal display apparatus, an electrophoretic display apparatus, a quantum dot display apparatus, a micro LED (Light Emitting Device) display apparatus, and a mini LED display apparatus. However, in the following description, the organic light emitting display apparatus will be described as an example for convenience of explanation.

Features of various embodiments of the present disclosure can be partially or entirely coupled to or combined with each other and can be operated, linked, or driven together in various ways. Embodiments of the present disclosure can be carried out independently from each other, or can be carried out together in co-dependent or related relationship.

Further, the term “can” encompasses all the meanings and coverages of the term “may.” The term “disclosure” is interchangeably used with, or encompasses all the meanings and coverages of, the term “invention.”

All the components of each display device or apparatus according to all embodiments of the present disclosure are operatively coupled and configured.

Hereinafter, various embodiments and examples of the present disclosure will be described in detail with reference to the attached drawings.

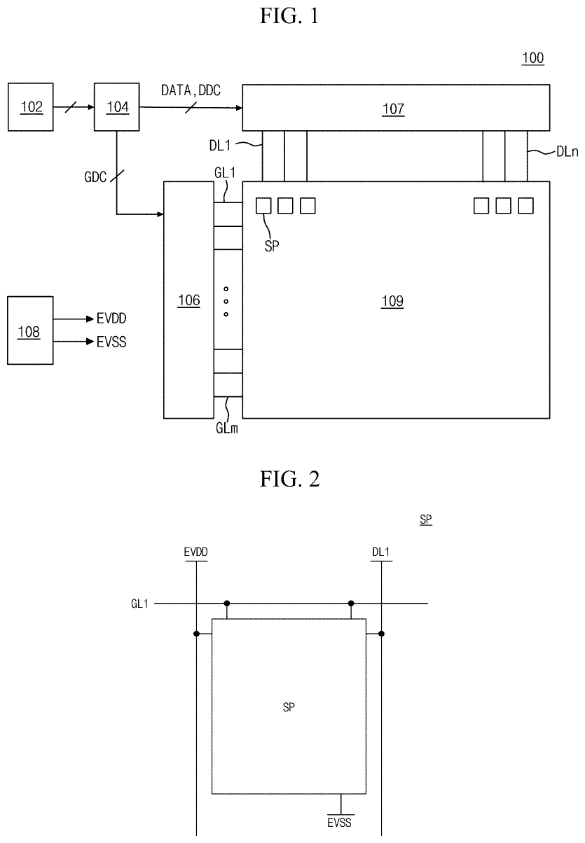

FIG. 1 is a schematic block diagram and FIG. 2 is a schematic block diagram of a sub-pixel of an organic light emitting display apparatus according to an aspect of this disclosure.

As shown in FIG. 1, an organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm where m is a real number such as a positive integer greater than 1. In this case, the gate driving unit 106 can be formed in the form of an integrated circuit (IC), but is not limited thereto. The gate driver 106 includes various gate driving circuits, and the gate driving circuits can be directly formed on the substrate 100. In this case, the gate driving unit 106 can be a gate-in-panel (GIP).

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn where n is a real number such as a positive integer greater than 1. In this case, the data driving 107 can be mounted on the upper surface of the display panel 109 in the form of an integrated circuit (IC), but is limited thereto.

The power supplying unit 108 outputs a high potential voltage VDD and a low potential voltage VSS etc. to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 108, the scan signal from the gate driving unit 106, and the power from the power supplying unit 108.

The display panel PAN includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel can be formed in the same area or can be formed in different areas.

As shown in FIG. 2, one sub-pixel SP can be connected to the gate line GL1, the data line DL1, the first power line EVDD, and the second power line EVSS. The sub-pixel SP can include a plurality of thin film transistors and a storage capacitor depending on the configuration of the pixel circuit. For example, the sub-pixel SP can include two transistors and one capacitor (it is called 2T1C), but is not limited thereto. The sub-pixel SP can be composed of 3T1C, 4T1C, 5T1C, 6T1C, 7T1C, 3T2C, 4T2C, 5T2C, 6T2C, 7T2, 8T2C, etc.

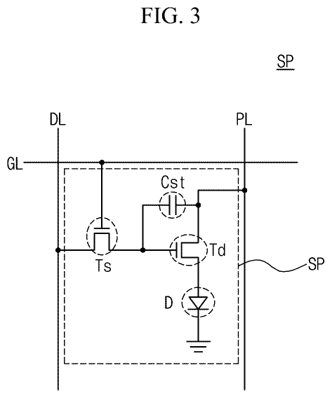

FIG. 3 is a circuit diagram illustrating the sub-pixel SP of the organic light emitting display apparatus 100 according to the present disclosure.

As shown in FIG. 3, the organic light emitting display apparatus 100 according to the present disclosure includes the gate line GL, the data line DL, and the power line PL crossing each other for defining the sub-pixel SP. A switching thin film transistor Ts, a driving thin film transistor DT, a storage capacitor Cst, and a light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the light emitting device D from the power line PL through the driving thin film transistor Td and then the light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors can be provided in the present disclosure.

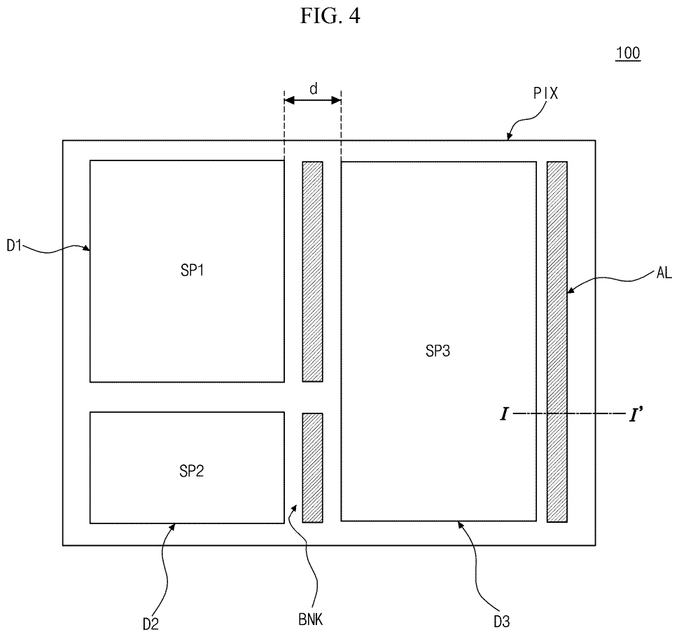

FIG. 4 is a plan view schematically illustrating a pixel PIX of the display apparatus 100 according to the first embodiment of this disclosure.

The display apparatus 100 according to the first embodiment of the present disclosure includes a plurality of pixels PIX. As shown in FIG. 4, each pixel PIX can include a plurality of sub-pixels SP1, SP2, and SP3. For example, the first sub-pixel SP1 can be a green sub-pixel that emits green light, the second sub-pixel SP2 can be a red sub-pixel that emits red light, and the third sub-pixel SP3 can be a blue sub-pixel. It can be a blue sub-pixel that emits light. However, it is not limited to this, and the first sub-pixel SP1 can be the red sub-pixel or the blue sub-pixel, and the second sub-pixel SP2 can be the green sub-pixel or the blue sub-pixel.

In the drawing, the sub-pixels SP1, SP2, and SP3 can be configured in an S-stripe manner in which the third sub-pixel SP3 is arranged vertically and the first and second sub-pixels SP1 and SP2 are arranged in the horizontal direction. However, it is not limited to this, and the sub-pixels SP1, SP2, and SP3 can be configured in a stripe method, delta method, or diamond method.

In the drawing, the area of the first sub-pixel SP1 is the middle, the area of the second sub-pixel SP2 is in the smallest, and the area of the third sub-pixel SP3 is the largest. However, the areas of the first to third sub-pixels SP1, SP2, and SP3 can all be the same. Further, the area of the first sub-pixel SP1 can be largest and the area of the third sub-pixel SP3 can be smallest. In the present disclosure, the first to third sub-pixels SP1, SP2, and SP3 can be formed to have various areas as needed.

A bank layer BNK is formed between the sub-pixels SP1, SP2, and SP3. The bank layer BNK is disposed to surround each of the sub-pixels SP1, SP2, and SP3 to partition the sub-pixels SP1, SP2, and SP3. In other words, a plurality of openings which are exposed to the outside are formed in the bank layer BNK, and sub-pixels SP1, SP2, and SP3 are defined by each opening.

The bank layer BNK can be formed a single layer, but can also be formed of multiple layers. For example, the bank layer BKN can be formed of a two-layer structure of a hydrophilic lower bank layer and a hydrophobic upper bank layer disposed on the hydrophilic lower bank layer. At this time, the width of the lower bank layer is wider than that of the upper bank layer, so that the lower bank layer and the upper bank layer have a stepped structure, but it is not limited thereto.

The light emitting elements D1, D2, and D3 can be disposed in each of the sub-pixels SP1, SP2, and SP3. For example, the first light emitting device D1 can be a green light emitting device that emits green light, the second light emitting device D2 can be a red light emitting device that emits red light. And the third light emitting device D3 can be a blue light emitting device that emits blue light. However, it is not limited to this, the first light emitting device D1 can be the red or blue light emitting devices, the second light emitting device D2 can be the green or blue light emitting devices, and the third light emitting device D3 can be the green or blue light emitting devices.

Each of the light emitting devices D1, D2, and D3 can include a first electrode, a second electrode, and an organic layer therebetween. The first electrode can be an anode electrode. The first electrode is formed in each sub-pixel SP1, SP2, SP3 and is electrically disconnected from the first electrode of the adjacent sub-pixel. A data voltage can be applied to the first electrode from an external data driving unit.

The organic layer is formed in the sub-pixels SP1, SP2, and SP3 and can be separated from the organic layer of the adjacent sub-pixel. In this case, for example, the green organic layer can be formed in the first sub-pixel SP), the red organic layer can be formed in the second sub-pixel SP2, and the blue organic layer can be formed in the third sub-pixel SP3, but not is limited thereto.

Further, the organic layer can be formed integrally throughout the sub-pixels SP1, SP2, and SP3. In this case, the organic layer can be a white organic layer that emits white light.

The second electrode can be a cathode electrode. The second electrode can be formed integrally throughout the display apparatus 100. A low potential voltage VSS can be supplied to the second electrode from an external power supply. As an example, the cathode electrode can also be separately formed in each of the sub-pixel SP1, SP2, SP3.

An auxiliary electrode AL can be disposed on one side of each sub-pixel SP1, SP2, and SP3. As an example, the auxiliary electrode AL can be disposed on one side of at least some sub-pixels SP1, SP2, and SP3. As an example, the auxiliary electrode AL can be disposed on one side of at least one of sub-pixels SP1, SP2, and SP3 in each pixel PIX. The auxiliary electrode AL can be electrically connected to the second power line and the second electrode of the sub-pixels SP1, SP2, and SP3, so that the low potential voltage VSS (for example, a common voltage) is applied to the second electrode through the second power line and the auxiliary electrode AL from the outside.

The auxiliary electrode AL is formed in each sub-pixel SP1, SP2, and SP3 for the following reason.

The second electrode is formed integrally in the entire area of the display apparatus 100. The low potential voltage is supplied to the set area of the second electrode and then the signal is transmitted to the entire area of the second electrode. Therefore, the signal is delayed due to the resistance of the second electrode depending on the position of the display apparatus 100. In particular, in the case of large area display apparatus, the signals are delayed more severely, so that the luminance is uneven depending on the location, and this luminance unevenness is an important cause of poor image quality.

Since the auxiliary electrode AL is made of the metal with good conductivity to apply the uniform voltage to the second electrode disposed over the entire area of the display apparatus 100, the image with uniform brightness is displayed over the entire area of the display apparatus 100.

In the present disclosure, the auxiliary electrode AL is disposed to correspond to each of the sub-pixels SP1, SP2, and SP3 and the low potential voltage is applied to the second electrode disposed in the corresponding sub-pixels SP1, SP2, and SP3, so that the defects caused by the signal delays can be minimized.

The auxiliary electrode AL can be disposed below the bank layer BNK between adjacent sub-pixels SP1, SP2, and SP3. For example, as shown in the figure, the auxiliary electrode AL can be disposed below the bank layer BNK on the right side of the sub-pixels SP1, SP2, and SP3. Further, as an example, the auxiliary electrode AL can be disposed on one or more sides of each of the sub-pixels SP1, SP2, and SP3. As an example, the auxiliary electrode AL can be disposed on the same side or different sides of the sub-pixels SP1, SP2, and SP3.

The auxiliary electrode AL is used to prevent defects due to signal delay by applying the low potential voltage to the second electrode without signal delay. Therefore, in the present disclosure, if the low potential voltage can be applied to the second electrode disposed in each sub-pixel SP1, SP2, and SP3 by the auxiliary electrode AL, the auxiliary electrode AL can be disposed at any position. As an example, the auxiliary electrode AL can be disposed at any layer below the bank layer BNK and the auxiliary electrode AL in the sub-pixels SP1, SP2, and SP3 can be disposed on the same layer or on different layers.

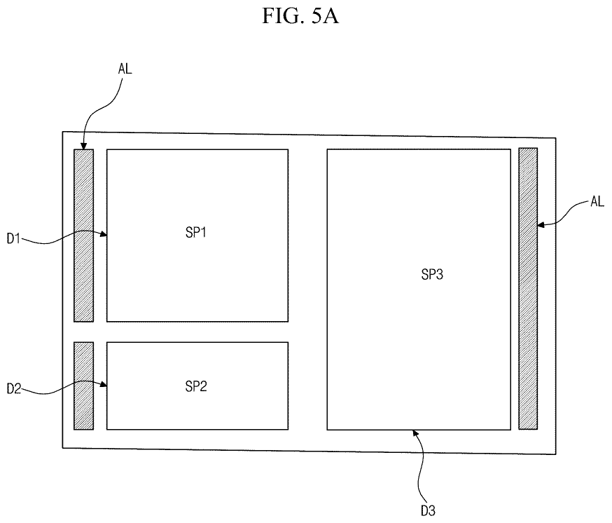

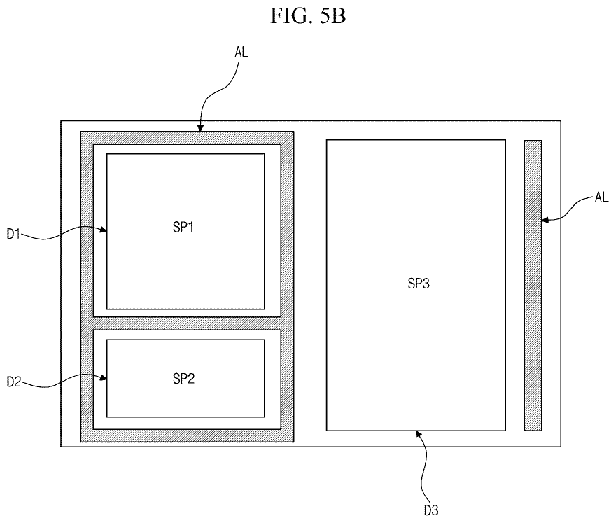

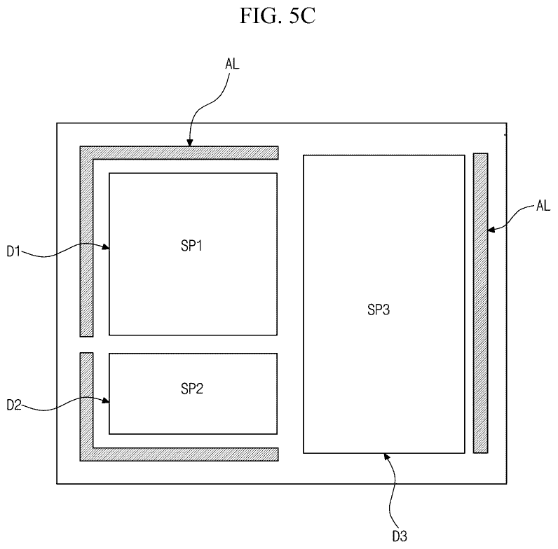

As shown in FIG. 5A, for example, the auxiliary electrode AL can be disposed below the bank layer BNK in the left side of the first sub-pixel SP1 and the second sub-pixel SP2, and the auxiliary electrode AL can be disposed below the bank layer BNK in the right side of the third sub-pixel SP3. The auxiliary electrode AL can be disposed below the bank layer BNK at the upper and/or lower regions of the sub-pixels SP1, SP2, and SP3.

As shown in FIG. 5B, for example, the auxiliary electrode AL can be disposed below the bank layer BNK surrounding the first and second sub-pixels SP1 and SP2, and the auxiliary electrode AL can be disposed below the bank layer BNK in the right side of the third sub-pixel SP3. Further, the auxiliary electrode AL can be disposed below the bank layer BNK surrounding the sub-pixels SP1, SP2, and SP3, and the auxiliary electrode AL can be disposed below the bank layer BNK surrounding two sub-pixels and in the right side of one sub-pixel SP.

As shown in FIG. 5C, for example, the auxiliary electrode AL can be disposed below the bank layer BNK in the left side and upper region of the first sub-pixel SP1, the auxiliary electrode AL can be disposed below the bank layer BNK in the left side and lower region of the second sub-pixel SP2, and the auxiliary electrode AL can be disposed below the bank layer BNK in the right side of the third sub-pixel SP3.

As described above, the auxiliary electrode AL is formed at various positions to apply the low potential voltage to the second electrode of the corresponding sub-pixels SP1, SP2, and SP3, so that the uniform voltage can be supplied to the entire area of the display apparatus 100.

In the present disclosure, high resolution can be realized and the aperture ratio of the sub-pixels SP1, SP2, and SP3 can be improved by minimizing the spacing d between adjacent sub-pixels SP1, SP2, and SP3. To realize this, in the present disclosure, the spacing d between the sub-pixels SP1, SP2, and SP3 is reduced, but the current flow path between the adjacent sub-pixels SP1, SP2, and SP3 is blocked to Minimize the lateral leakage current between the adjacent sub-pixels SP1, SP2, and SP3. Further, in the present disclosure, the deterioration of the organic layer due to moisture can be minimized by blocking moisture penetration between adjacent sub-pixels SP1, SP2, and SP3.

Hereinafter, this is explained in more detail.

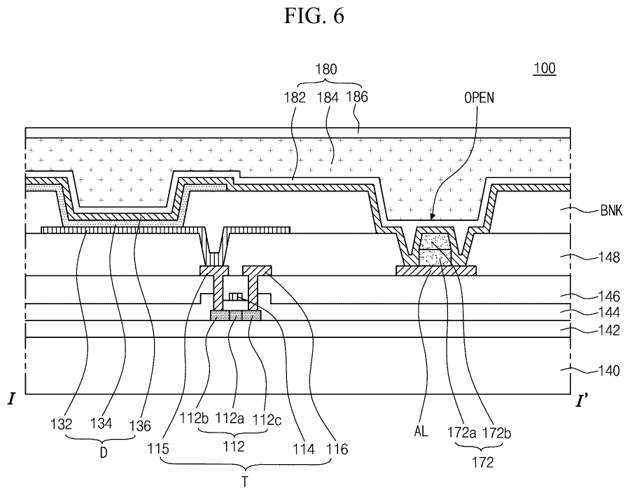

FIG. 6 is a cross-sectional view showing the structure of the sub-pixel of the display apparatus 100 according to the first embodiment of the present disclosure, which is the cross-sectional view taken along line I-I′ of FIG. 4. At this time, although the structure of the third sub-pixel SP3 is shown in FIG. 6, the structures of the first sub-pixel SP1 and the second sub-pixel (SP2) are also the same.

As shown in FIG. 6, a buffer layer 142 is formed on a substrate 140. The substrate 140 can be made of a hard material such as a glass or flexible material such as a plastic material, but not limited thereto. For example, the plastic material can include a polyimide, a polymethylmethacrylate, a polyethylene terephthalate, a Polyethersulfone, and a Polycarbonate.

When the substrate 140 is made of polyimide, the substrate 140 can be made of a plurality of polyimide layers, and an inorganic layer can be further disposed between the polyimide layers, but is not limited thereto.

The buffer layer 142 can be formed in the entire area of the substrate 140 to enhance adhering force between the substrate 140 and the layers thereon. Further, the buffer layer 142 can block various types of defects, such as alkali components flowing out from the substrate 140. In addition, the buffer layer 142 can delay diffusion of moisture or oxygen penetrating into the substrate 140.

The buffer layer 142 can be a single layer made of silicon oxide (SiOx) or silicon nitride (SiNx), or multi-layers thereof. When the buffer layer 142 is made of multiple layers, SiOx and SiNx can be alternately formed. The buffer layer 142 can be omitted based on the type and material of the substrate 140, the structure and type of the thin film transistor, and the like.

A thin film transistor is formed on the buffer layer 142 in the display area AA. For convenience of description, only the driving thin film transistor among various thin film transistors that can be disposed in the display area AA is illustrated, but other thin film transistors such as switching thin film transistors can also be included. In the figure, the thin film transistor of a top gate structure is shown, but the thin film transistor is not limited to this structure and can be formed in other structures such as the thin film transistor of a bottom gate structure.

The thin film transistor includes a semiconductor layer 112 disposed on the buffer layer 142, a gate insulating layer 144 covering the semiconductor layer 112, a gate electrode 114 on the gate insulating layer 144, an interlayer insulating layer 146 covering the gate electrode 114, and a source electrode 115 and a drain electrode 116 on the interlayer insulating layer 146.

The semiconductor layer 112 can be made of a polycrystalline semiconductor. For example, the polycrystalline semiconductor can be made of low temperature poly silicon (LTPS) having high mobility, but is not limited thereto.

The semiconductor layer 112 can be made of an oxide semiconductor. For example, semiconductor layer 112 can be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor layer 112 includes a channel region 112a in a central region and a source region 112b and a drain region 112c which are doped layers at the both sides of the channel region 112a.

The gate insulating layer 144 can be formed in the display area AA and the non-display area NA or formed only in the display area AA, or can be patterned for the semiconductor layer 112 of each thin film transistor, without being limited thereto. The gate insulating layer 144 can be composed of a single layer or multiple layers made of an inorganic material such as SiOx or SiNx, but is not limited thereto.

The gate electrode 114 is made of a metal. For example, the gate electrode 114 can be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 can be formed in the display area AA and the non-display area NA, but the interlayer insulating layer 146 can be formed only in the display area AA. The interlayer insulating layer 146 can be made of the organic material such as photo-acryl, or the interlayer insulating layer 146 can formed of the single layer or the multiple layers made of the inorganic material such as SiOx or SiNx, but is not limited thereto. Further, the interlayer insulating layer 146 can be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 can be respectively contacted to the source region 112b and the drain region 112c of the semiconductor layer 112 through contact holes formed in the gate insulating layer 144 and the interlayer insulating layer 146.

A bottom shield metal layer can be disposed on the substrate 140 under the semiconductor layer 112. The bottom shield metal layer minimizes a backchannel phenomenon caused by charges trapped in the substrate 140 to prevent afterimages or deterioration of transistor performance. The bottom shield metal layer can be composed of the single layer or the multi layers made of titanium (Ti), molybdenum (Mo), or an alloy thereof, but is not limited thereto.

A planarization layer 148 is formed on the substrate where the thin film transistor T is disposed. The planarization layer 148 can be formed of the organic material such as photoacrylic. But it is not limited thereto. The planarization layer 148 can include a plurality of layers including the inorganic layer and the organic layer.

A light emitting device D is disposed on the planarization layer 148. The light emitting device D includes a first electrode 132, an organic layer 134, and a second electrode 136.

The first electrode 132 is disposed on the planarization layer 148 and electrically connected to the drain electrode 116 of the thin film transistor through the contact hole formed in the planarization layer 148. The first electrode 132 can be formed of at least one of silver (Ag), aluminum (Al), gold (Au), molybdenum (Mo), tungsten (W), chromium (Cr), or an alloy thereof. Further, the first electrode 132 can be formed of a transparent metal oxide material such as indium tin oxide (ITO) or indium zinc oxide (IZO).

When the display apparatus 100 is a top emission type display apparatus, the first electrode 132 can further include an opaque conductive material layer to function as a reflective electrode that reflects light. When the display apparatus 100 is a bottom emission type display apparatus, the first electrode 132 can be made of the transparent conductive material such as ITO or IZO.

A bank layer BNK is formed at the boundary between the sub-pixels on the planarization layer 148. The bank layer 152 can be a barrier wall to define sub-pixels. The bank layer BNK divides each sub-pixel to prevent light of a specific color output from adjacent pixels from being mixed and output.

The bank layer BNK is made of at least one material of the inorganic insulating material such as SiNx or SiOx, the organic insulating material such as BenzoCycloButene, acrylic resin, epoxy resin, phenolic resin, polyamide resin, or the photosensitizer including black pigment, but is not limited thereto.

The organic layer 134 is formed on the upper surface of the first electrode 132, the inclined surface of the bank layer BNK, or the partial region of the upper surface of the bank layer BNK. The organic layer 134 is formed in the R, G, and B sub pixels and can include an R-emitting layer for emitting red light, a G-emitting layer for emitting green light, and a B-emitting layer for emitting blue light. For example, the organic layer 134 can include an organic light emitting layer, an inorganic light emitting layer, a nano-sized material layer, a quantum dot layer, a micro LED light emitting layer, or a mini LED light emitting layer, but is not limited thereto.

The organic layer 134 can further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the organic layer 134 and can be formed of the single layer or the multi layers made of the metal or the alloy thereof. Further, the second electrode 136 can be made of the transparent metal oxide material such as ITO or IZO, but is not limited thereto.

When the display apparatus 100 is the top emission type, the second electrode 136 can be made of the half-transparent conductive material that transmits light. For example, the second electrode 188 can be made of at least one or more of the alloys such as LiF/Al, CsF/Al, Mg:Ag, Ca/Ag, Ca:Ag, LiF/Mg:Ag, LiF/Ca/Ag, or LiF/Ca:Ag.

When the display apparatus 100 is the bottom emission type, the second electrode 136 can be the reflective electrode made of the opaque conductive material. For example, the second electrode 188 can be made of at least one or more of silver (Ag), aluminum (Al), gold (Au), molybdenum (Mo), tungsten (W), chromium (Cr), or alloys thereof.

Further, the light emitting device D can be formed in a tandem structure. The tandem structure can include a plurality of organic light emitting layers and a charge generating layer disposed between the organic light emitting layers. The charge generating layer is disposed to adjust the charge balance between the plurality of organic light emitting layers, and can be formed of a plurality of layers including a first charge generating layer and a second charge generating layer. The charge generating layer can include an N-type charge generating layer and a P-type charge generating layer. In this case, the charge generating layer can be formed of the organic layer doped with an alkali metal such as Li, Na, K, or Cs or an alkaline earth metal such as Mg, Sr, Ba, or Ra, but is not limited thereto.

The first electrode 132 and the organic layer 134 are disposed in each sub-pixel and are disconnected from the first electrode 132 and the organic layer 134 of the adjacent sub-pixel, while the second electrode 136 is formed integrally in the entire area of the display apparatus 100. Accordingly, the corresponding data voltage, for example, the pixel voltage, can be applied to the first electrode 132 of each sub-pixel, and the low potential voltage, for example, the common voltage, can be applied to the second electrode 136 formed in all sub-pixels.

The auxiliary electrode AL is disposed on the interlayer insulating layer 146 below the bank layer BNK. The planarization layer 148 and the bank layer BNK on the auxiliary electrode AL are removed to form an opening OPEN, and the auxiliary electrode AL is exposed to the outside through the opening OPEN. The auxiliary electrode AL exposed to the outside is electrically connected to the second electrode 136 through the opening OPEN. As described above, since the auxiliary electrode AL is formed in each sub-pixel and the auxiliary electrode AL is electrically connected to the second electrode 136 in the present disclosure, the common voltage can be applied to the second electrode 136 without the signal delay even in the large-area display apparatus 100.

A blocking layer 172 is formed on the auxiliary electrode AL. At this time, since the width of the blocking layer 172 is smaller than that of the auxiliary electrode AL, the auxiliary electrode AL extends to both sides of the blocking layer 172 and the extended area is exposed to the outside. The second electrode 136 extends from the light emitting device D to the top and side surfaces of the blocking layer 172, so that the second electrode 136 is formed on the surface of the exposed area of the auxiliary electrode AL at the both sides of blocking 172, so the second electrode 136 is electrically connected to the auxiliary electrode AL. Embodiments are not limited thereto. As an example, as long as the blocking layer 172 exposes a portion of the auxiliary electrode AL, the size and shape of the blocking layer 172 is not limited. As an example, the width of the blocking layer 172 can be equal to or greater than that of the auxiliary electrode AL. As an example, the blocking layer 172 can be shifted with respect to the auxiliary electrode AL. As an example, the blocking layer 172 may expose one side area of the auxiliary electrode AL. As an example, the second electrode 136 may extend from the light emitting device D to the top and side surfaces of the blocking layer 172, so that the second electrode 136 is formed on the surface of the exposed portion of the auxiliary electrode AL at the one side of the blocking layer 172.

The blocking layer 172 can include a first pattern 172a on the auxiliary electrode AL and a second pattern 172b thereon. At this time, the first pattern 172a can be made of a material with orthogonality, and the second pattern 172b can be made of photoresist.

Orthogonality means that any two elements in a set have independent properties. The orthogonality means that different configurations formed inside the display apparatus 100 have different properties. For example, since a specific layer inside the display apparatus 100 has completely different properties from other layers, the materials with orthogonality have little effect on other materials.

Further, the orthogonality can be understood as a characteristic in which two objects exist independently, regardless of each other. For example, the material having orthogonality can have both hydrophobicity having a low affinity for water and oleophobicity having a low affinity for oil.

As such, since the first pattern 172a has the orthogonality, the chemical damage does not occur between the first pattern 172a and other layers, and other layers are not physically damaged when patterning the first pattern 172a. In the present disclosure, as the orthogonal material, a fluoropolymer material containing a large amount of fluorine (F) in the functional while carbon-carbon bonds are formed continuously in a chain structure can be used, but is limited thereto.

Further, since the first pattern 172a has both hydrophobicity and oleophobicity, it can separate from or reject moisture. Accordingly, the first pattern 172a can block moisture or oxygen flowing into the sub-pixel.

The width of the lower surface of the second pattern 172b is the same as the width of the upper surface of the first pattern 172a, and the side surface of the second pattern 172b is formed in a tapered shape. Therefore, when the second electrode 136 is formed on the top and side surfaces of the blocking layer 172, the second electrode 136 is not disconnected in the side surface of the second pattern 172b of the blocking layer 172. In this way, since the second electrode 136 is formed on the upper surface of the auxiliary electrode AL exposed on both sides of the blocking layer 172 and on the upper surface and side of the blocking layer 172 without disconnection, the voltage from the outside through the auxiliary electrode AL can be supplied to the second electrode 136 without delay.

The lateral current between adjacent sub-pixels mainly leaks through the organic layer 134. In the present disclosure, the organic layer 134 is formed only in the corresponding sub-pixel and is disconnected from the organic layer formed in the adjacent sub-pixel, thereby blocking the path of the leakage current between adjacent sub-pixels. Thus, it is possible to prevent lateral leakage current between adjacent sub-pixels.

In the present disclosure, since the flow path of lateral leakage current between adjacent sub-pixels can be blocked, it is possible to prevent the lateral leakage current even when the gap between adjacent sub-pixels is minimized. Accordingly, by minimizing the gap between adjacent sub-pixels, the area of the sub-pixels, for example, the light emitting area, can be maximized and also achieve high resolution.

Further, in the present disclosure, since the first pattern 172a is made of an orthogonal material, it is possible to block moisture from penetrating into the corresponding sub-pixel, thereby preventing deterioration of the light emitting device D due to moisture.

Referring again to FIG. 6, an encapsulation layer 180 is formed on the second electrode 136 of the light emitting device D. When the light emitting device D is exposed to impurities such as moisture or oxygen, a pixel shrinkage phenomenon in which the light emitting area is reduced or the defect such as a dark spot in the light emitting area can occur. Further, moisture or oxygen penetrating into the light emitting device D oxidizes the metal electrode. The encapsulation layer 180 blocks impurities such as the oxygen and the moisture from the outside to prevent defects of the light emitting device D and various electrodes.

The encapsulation layer 180 can be formed of a first encapsulation layer 182, a second encapsulation layer 184, and a third encapsulation layer 186, but is not limited thereto. The encapsulation layer 180 can be formed of two layers or four or more layers.

The first encapsulation layer 182 and the third encapsulation layer 186 can be made of the inorganic material such as SiOx or SiNx, but are not limited thereto. The second encapsulation layer 184 can be made of the organic insulating material such as acrylic resin, epoxy resin, polyimide, polyethylene, or silicon oxycarbon (SiOC), but is not limited thereto. Further, the third encapsulation layer 186 can be made of thin metal (Face Seal Metal), but is not limited thereto.

A touch member can be disposed on the encapsulation layer 180. The touch member can detect external touch information using the user's finger or a touch pen.

As described above, in the display apparatus 100 according to the first embodiment of the present disclosure, the organic layer 136 that emits monochromatic light is formed in each sub-pixel and the auxiliary electrode is formed between adjacent sub-pixels to supply the low potential voltage or the common voltage to the second electrode 136 of the light emitting device D. further, in the present disclosure, the blocking layer 172 having the orthogonal material, for example, the organic material containing fluorine, is formed on the auxiliary electrode between sub-pixels.

Accordingly, the display apparatus 100 according to the first embodiment of the present disclosure can achieve the following effects.

First, in the present disclosure, the organic layer 136 that emits monochromatic light, for example, the organic layers 136 that emits green light, red light, and blue light, is respectively formed in each sub-pixel. Accordingly, since the organic layer 136 is disconnected between adjacent sub-pixels, the current flow path between adjacent sub-pixels is eliminated, and as a result the lateral leakage current between adjacent sub-pixels can be prevented.

Second, in the present disclosure, since the auxiliary electrode AL is disposed in each sub-pixel and the auxiliary electrode AL is electrically connected to the second electrode 136 of the corresponding sub-pixel to apply the low potential voltage to the second electrode 136, the signal delay or the voltage drop due to resistance of the second electrode 136 can be prevented. In particular, since the signal delay or the voltage drop in the entire area of the large area display apparatus 100 can be prevented, the image quality degradation such as the luminance unevenness depending on location can be prevented.

Third, in the present disclosure, the blocking layer 172 is disposed on the auxiliary electrode AL, and the blocking layer 172 is formed of the first pattern 172a having orthogonality and the second pattern 172b on the first pattern 172a. The material having orthogonality can have both hydrophobic properties which have the low affinity for water and oleophobic properties which have a low affinity for oil, so that the moisture or the oxygen flowing into the sub-pixel can be blocked.

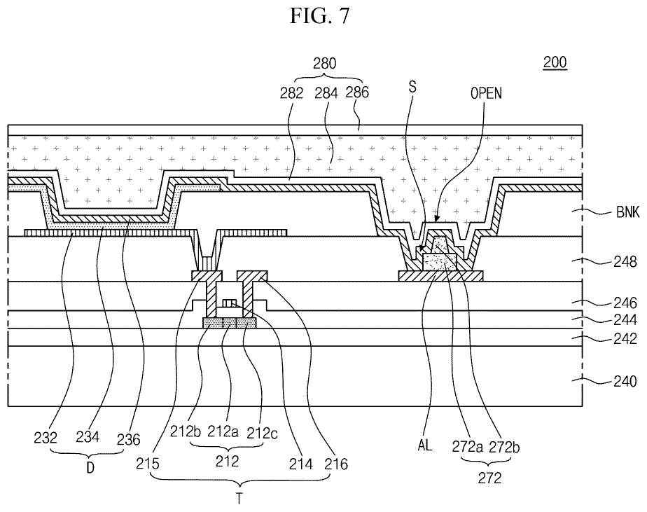

FIG. 7 is the cross-sectional view showing the structure of the sub-pixel of the display apparatus 200 according to the second embodiment of the present disclosure. At this time, the description of the same structure as the first embodiment will be omitted or simplified, and only the different structures will be described in detail.

As shown in FIG. 7, in the display apparatus 200 according to the second embodiment of the present disclosure, the thin film transistor T and the light emitting element D are disposed over the substrate 240.

The thin film transistor T includes the semiconductor layer 212 disposed on the buffer layer 242, the gate electrode 214 disposed on the gate insulating layer 244, the source electrode 215 and the drain electrode 216 disposed on the interlayer insulating layer 246.

The light emitting device D includes the first electrode 232 and the organic layer 234 disposed in each sub-pixel, and the second electrode 236, which is the common layer formed in the entire sub-pixels.

The sub-pixels are partitioned by the bank layer BNK. The bank layer BNK and the planarization layer 248 between sub-pixels are partially removed to form the opening OPEN, and the auxiliary electrode AL is formed on the interlayer insulating layer 246 within the opening OPEN.

Further, the blocking layer 272 is formed on the auxiliary electrode AL. At this time, since the width of the blocking layer 272 is smaller than that of the auxiliary electrode AL, the auxiliary electrode AL is extended to both sides of the blocking layer 272 and is exposed to the outside. Since the second electrode 236 disposed in the entire sub-pixels is extended within the opening OPEN, the second electrode 236 is formed on the exposed upper surfaces of the auxiliary electrode AL and on the side and upper surfaces of the blocking layer 272, and thus the second electrode 236 is electrically connected to the auxiliary electrode AL.

The blocking layer 272 includes the first pattern 272a and the second pattern 272b thereon. The first pattern 272a can be made of the orthogonal material, specially the fluoropolymer material containing the large amount of fluorine (F) in the functional while carbon-carbon bonds are formed continuously in a chain structure, but is limited thereto. The second pattern 272b can be made of photoresist.

In this embodiment, since the width of the first pattern 272a is larger than that of the second pattern 272b, the step S is formed between the first pattern 272a and the second pattern 272b. In the display apparatus 100 of the first embodiment shown in FIG. 6, the first pattern 172a and the second pattern 172b have the same width, whereas in the display apparatus 200 of this embodiment, the width of the first pattern 272a is larger than that of the second pattern 272b.

Therefore, the width of the first pattern 172a of the display apparatus 100 according to the first embodiment is smaller than that of the first pattern 272a of the display apparatus 200 according to the second embodiment. Since the first pattern 272a is made the orthogonal material having hydrophobicity with the low affinity to the water and oleophobicity with the low affinity to the oil, it can block moisture or oxygen penetrating into the sub-pixel. In particular, the width of the first pattern 272a of the second embodiment is larger than the width of the first pattern 172a in the first embodiment, so that the length of the penetration path of the moisture in the first pattern 272a is increased compared to the length of the penetration path of the moisture in the first pattern 172a when the moisture penetrates into the sub-pixel. As a result, moisture and oxygen can be blocked more effectively.

Further, in second embodiment, since the step S is formed between the first pattern 272a and the second pattern 272b, the adhesion of the second electrode and the blocking layer 270 can be improved by the step S when the second electrode 236 is formed on the side and upper surfaces of the blocking layer 270.

Referring again to FIG. 7, the encapsulation layer 280 is disposed over the second electrode 236. The encapsulation layer 280 can include first and third encapsulation layers 282 and 286 made of the inorganic material and a second encapsulation layer 284 made of the organic material disposed therebetween.

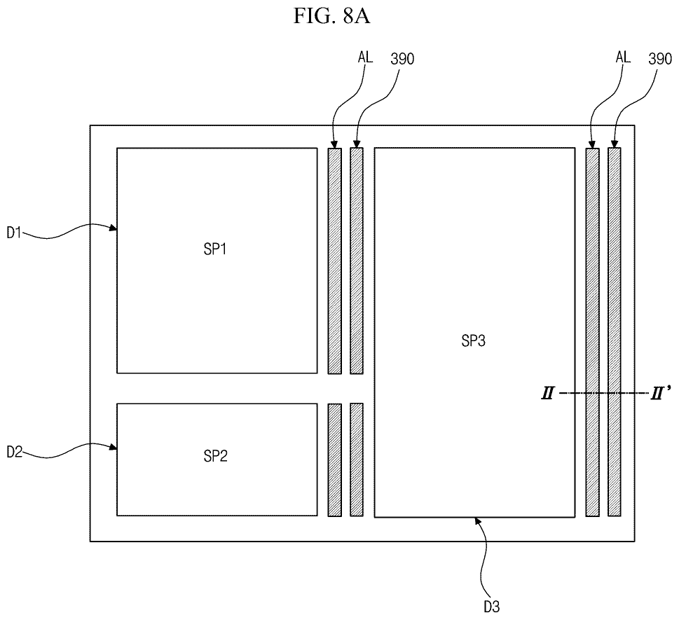

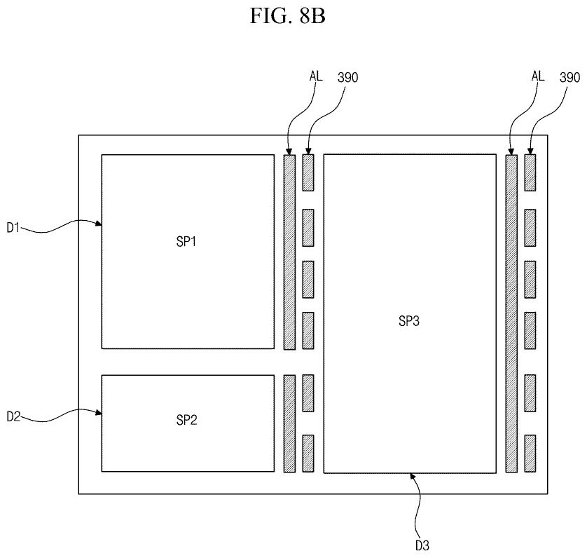

FIGS. 8A and 8B are plan views of the display apparatus 300 according to the third embodiment of the present disclosure.

As shown in FIG. 8A, the display apparatus 300 according to this embodiment includes a plurality of first to third sub-pixels SP1, SP2, and SP3. At this time, the first sub-pixel SP1 can be the green sub-pixel, the second sub-pixel SP2 can be the red sub-pixel, and the third sub-pixel SP3 can be the blue sub-pixel, but are not limited thereto.

Each of the plurality of first to third sub-pixels SP1, SP2, and SP3 is surrounded by the bank layer BNK to be separated from adjacent sub-pixels. the auxiliary electrode AL is disposed in the opening formed in the bank layer BNK and is electrically connected to the second electrode of the light emitting element D1, D2, and D3 of the corresponding sub-pixels SP1, SP2, and SP3.

Further, a disconnection unit 390 is formed at one side of the auxiliary electrode AL on the bank layer BNK. The disconnection unit 390 disconnects the second electrode of the light emitting device D1, D2, and D3 to block the moisture or the oxygen from flowing into the sub-pixel SP1, SP2, and SP3 along the interface of the second electrode.

In the figure, the disconnection unit 390 is disposed at one side of the sub-pixels SP1, SP2, and SP3, but it is not limited thereto. The disconnection unit 390 can be disposed at the both sides of the sub-pixels SP1, SP2, and SP3, or can be disposed at the upper and lower regions of the sub-pixels SP1, SP2, and SP3. Further, the disconnection unit 390 can surround the sub-pixels SP1, SP2, and SP3. Although it is illustrated that the disconnection unit 390 is disposed at the same side as the auxiliary electrode AL, embodiments are not limited thereto. As an example, the disconnection unit 390 can be disposed at a different side from the auxiliary electrode AL. As an examiner, the disconnection unit 390 may have the same length as or a different length from the auxiliary electrode AL.

As described above, in this embodiment, since the impurities such as moisture and oxygen flowing into the sub-pixels SP1, SP2, and SP3 can be blocked more efficiently by the disconnection unit 390, the deterioration of the light emitting device caused by moisture or oxygen, etc. can be prevented.

FIG. 8B is the diagram showing another structure of the display apparatus 300 according to the third embodiment of the present disclosure.

As shown in FIG. 8B, in the display apparatus 300 of this structure, the disconnection unit 390 is disposed at one side of the sub-pixels SP1, SP2, and SP3. At this time, the disconnection unit includes a plurality of disconnection units 390 spaced apart from each other at a predetermined distance and disconnects a portion of the second electrode of the light emitting device D1, D2, and D3. Therefore, moisture or oxygen is prevented from penetrating through the boundary of the second electrode. Further, since the second electrode is electrically connected over the entire area by the regions between the disconnection units 390, a uniform low potential voltage can be applied to the entire area.

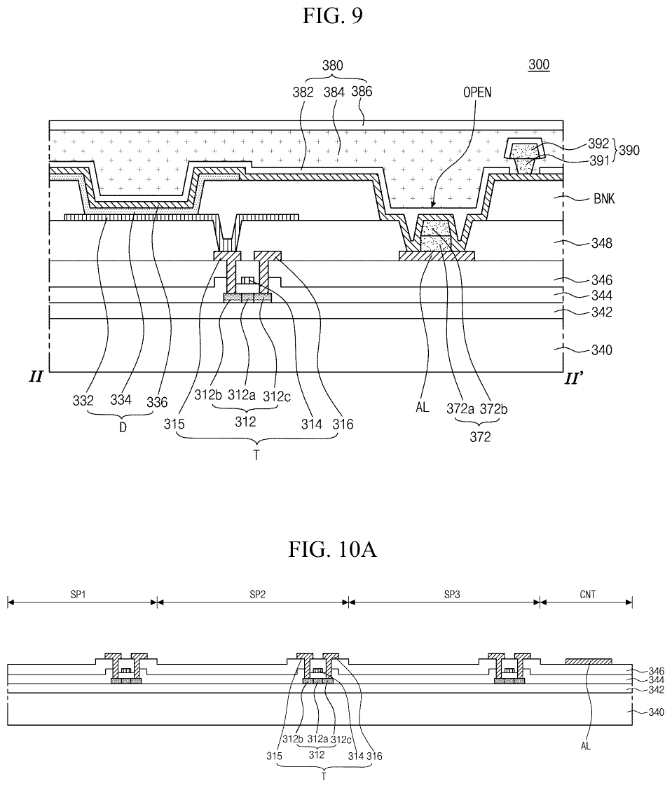

FIG. 9 is the view specifically showing the structure of the display apparatus 300 according to the third embodiment of the present disclosure, and is a cross-sectional view taken along line II-II′ of FIG. 8A. At this time, the description of the same structure as the first embodiment shown in FIG. 6 will be omitted or simplified, and only the different structures will be described in detail.

As shown in FIG. 9, in the display apparatus 300 according to the third embodiment of the present disclosure, the thin film transistor T and the light emitting element D are disposed over the substrate 340.

The thin film transistor T includes the semiconductor layer 312 disposed on the buffer layer 342, the gate electrode 314 disposed on the gate insulating layer 344, the source electrode 315 and the drain electrode 316 disposed on the interlayer insulating layer 346.

The light emitting device D includes the first electrode 332, the organic layer 334 disposed in each sub-pixel, and the second electrode 336, which is a common layer formed in the entire sub-pixels.

The sub-pixels are partitioned by the bank layer BNK. The bank layer BNK and the planarization layer 348 between sub-pixels are partially removed to form the opening OPEN, and the auxiliary electrode AL is formed on the interlayer insulating layer 346 within the opening OPEN.

The blocking layer 372 is formed on the auxiliary electrode AL. At this time, since the width of the blocking layer 372 is smaller than that of the auxiliary electrode AL, the auxiliary electrode AL extends to both sides of the blocking layer 372 and the extended area is exposed to the outside. The second electrode 336 formed in the entire sub-pixels extends to the inside of the opening OPEN, so that the second electrode 336 is formed in the upper surface of the auxiliary electrode AL exposed to the outside in the both sides of the blocking layer 372 and on the side and upper surfaces of the blocking layer 372 and then the second electrode 336 is electrically connected to the auxiliary electrode AL.

The blocking layer 372 includes the first pattern 372a and the second pattern 372b thereon. The first pattern 372a can be made of the orthogonal material, specially the fluoropolymer material containing the large amount of fluorine (F) in the functional while carbon-carbon bonds are formed continuously in a chain structure, but is limited thereto. The second pattern 272b can be made of photoresist.

Since the first pattern 372a is made the orthogonal material having hydrophobicity with the low affinity to the water and oleophobicity with the low affinity to the oil, it can block moisture or oxygen penetrating into the sub-pixel.

The disconnection unit 390 is disposed over the bank layer BNK in one side of the blocking layer 372. The disconnection unit 390 includes a first disconnection layer 391 and a second disconnection layer 392 thereon, where the width of the upper surface of the first disconnection layer 391 is smaller than that of the lower surface of the second disconnection layer 392, so that the disconnection unit 390 is formed in an undercut shape.

Therefore, when the second electrode 336 of the light emitting device D is formed on the disconnection unit 390, the second electrode 336 is disconnected in the disconnection unit 390 due to the undercut shape, so that moisture or oxygen flowing into the sub-pixel along the interface of the second electrode 336 can be blocked by the disconnected area of the second electrode 336.

The first disconnection layer 391 can be made of the orthogonal material, specially the fluoropolymer material containing the large amount of fluorine (F) in the functional while carbon-carbon bonds are formed continuously in a chain structure, but is limited thereto. The second disconnection layer 392 can be made of photoresist.

Referring again to FIG. 9, the encapsulation layer 380 is disposed over second electrode 336 of the light emitting device D. The encapsulation layer 380 includes the first and third encapsulation layers 382 and 386 made of the inorganic material and the second encapsulation layer 384 made of the organic material disposed therebetween.

When the encapsulation layer 380 is formed on the disconnection unit 390, the adhesion of the encapsulation layer 380 can be reduced on the upper portion of the disconnection unit 390 and then the encapsulation layer 380 can be peeled off, due to the undercut shape of the disconnection unit 390.

As shown in FIG. 8B, when the disconnection unit includes a plurality of disconnection units 390 spaced apart from each other by a certain distance, the area where the adhesion of the encapsulation layer 380 is reduced is reduced by the disconnection units 390, so that the peeled off-phenomenon of the encapsulation layer 380 can be reduced. For example, in the structure shown in FIG. 8B, the disconnection units 390 can prevent penetration of foreign substances such as moisture or oxygen and reduce the peeled-off phenomenon of the encapsulation layer 380.

Hereinafter, the manufacturing method of the display apparatus according to the present disclosure will be described in detail with reference to the attached drawings. At this time, for convenience of explanation, the display apparatus 300 having the structure shown in FIG. 9 will be described as an example.

In general, the organic layer, which is the light emitting layer of the display apparatus, is formed by depositing organic materials on a plurality of sub-pixels using a fine metal mask made of a thin metal. However, when using the metal mask, the central part of the mask sags due to the weight of the metal. This sagging becomes more severe, especially when manufacturing large area display apparatus. Further, since it was difficult to form the metal mask into the fine pattern, there were limitations in manufacturing high resolution display apparatus.

To solve this issue, the method of forming the organic layer by a photo process has been proposed. The photo process includes the process of applying the organic material, the process of forming the photoresist layer on the organic material, the process of developing the photoresist, and the process of etching the organic material by the patterned photoresist pattern.

However, in this photo process, there is a problem that the organic layer is deteriorated by the damage caused by the high temperature heat and developer during the photoresist development process.

In the present disclosure, by forming the organic layer using a lift-off method, it is possible to prevent damage to the organic layer by the developer or the high temperature heat.

Hereinafter, the manufacturing method of the display apparatus according to the present disclosure will be described in detail. At this time, for convenience of explanation, the method of manufacturing the display apparatus 300 according to the third embodiment of the present disclosure shown in FIG. 9 will be described.

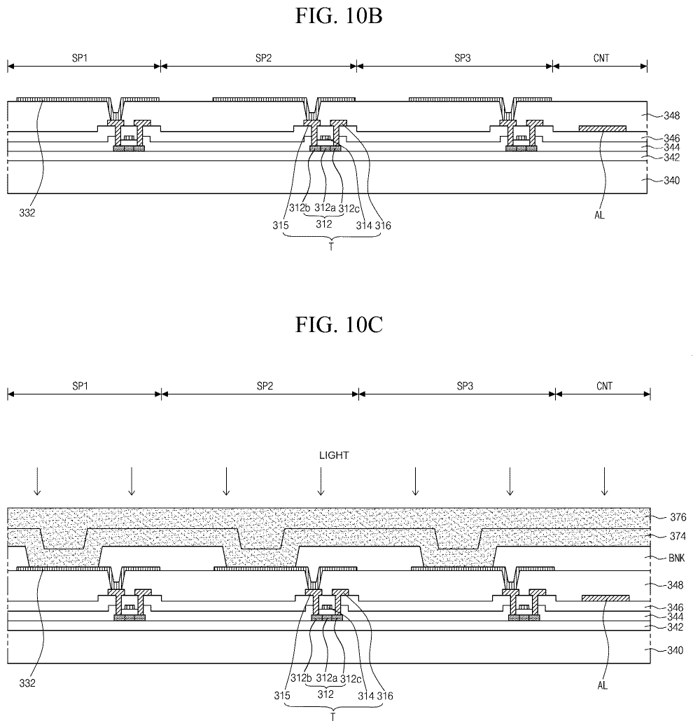

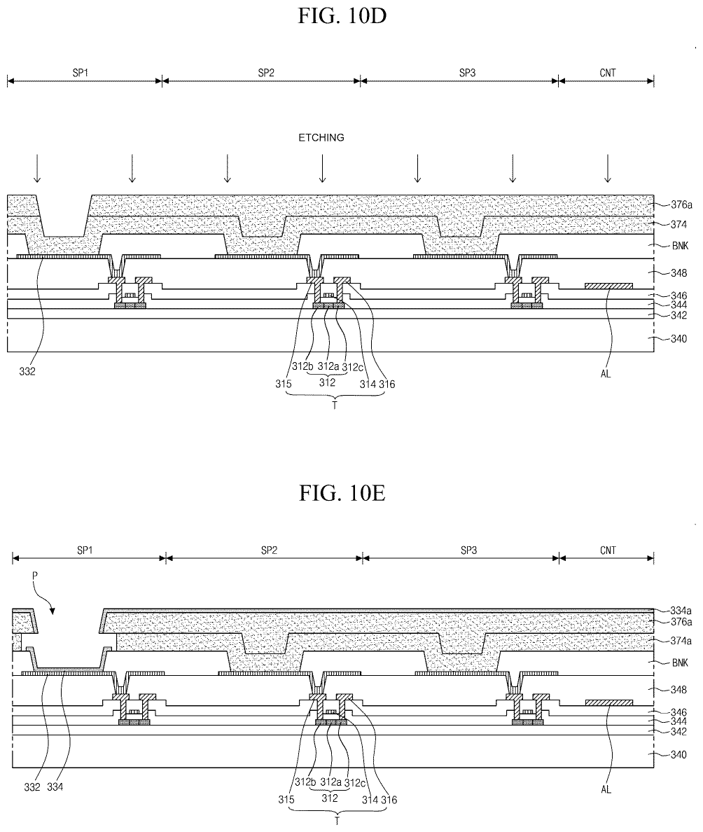

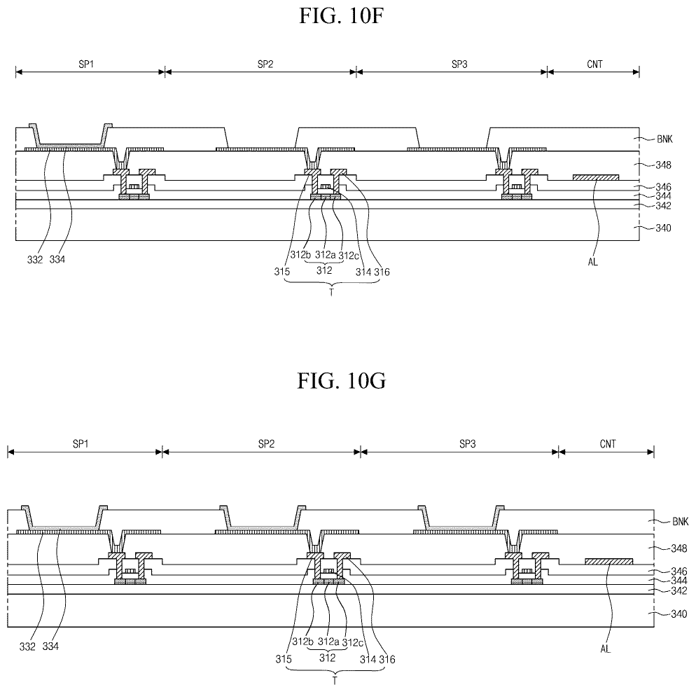

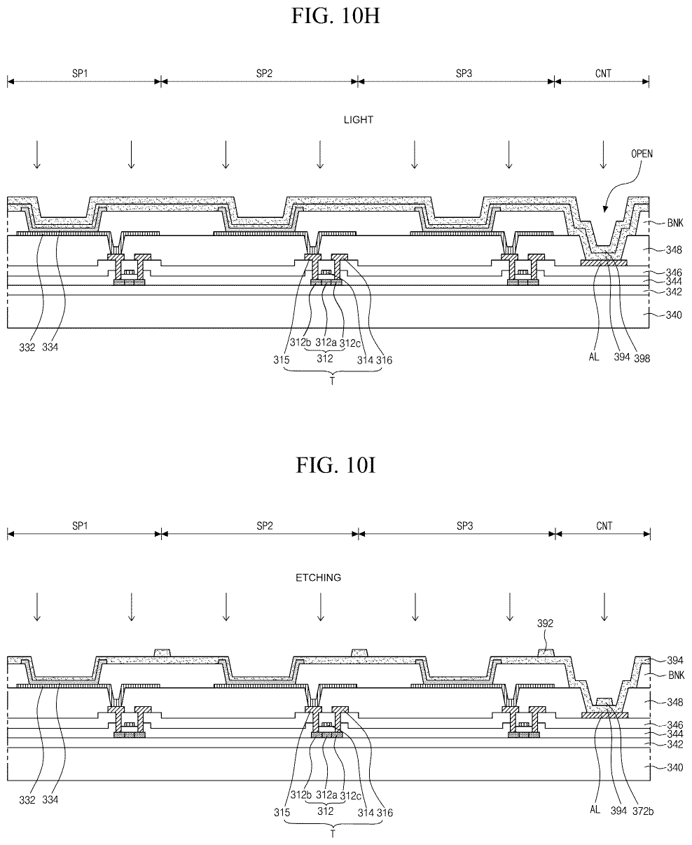

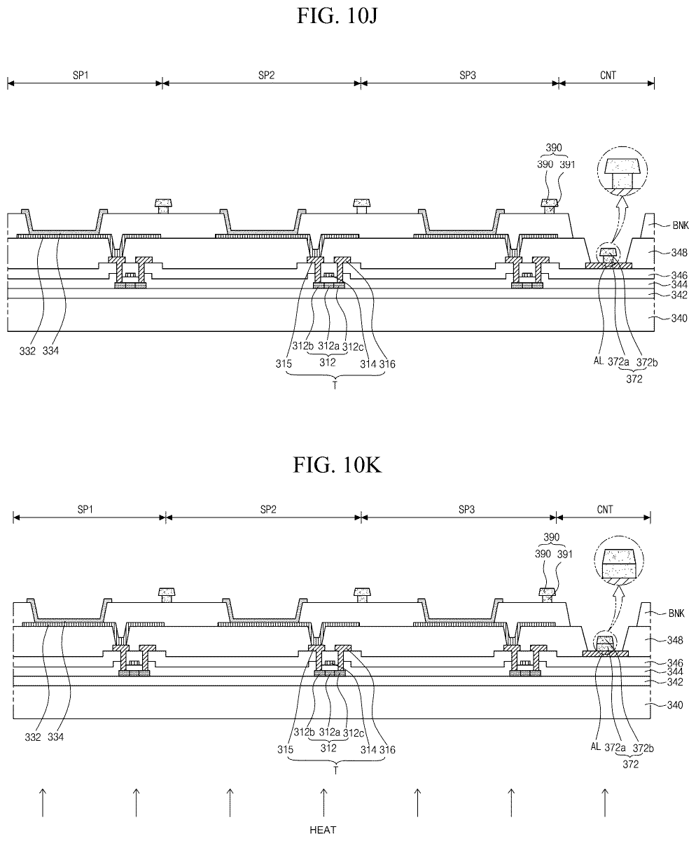

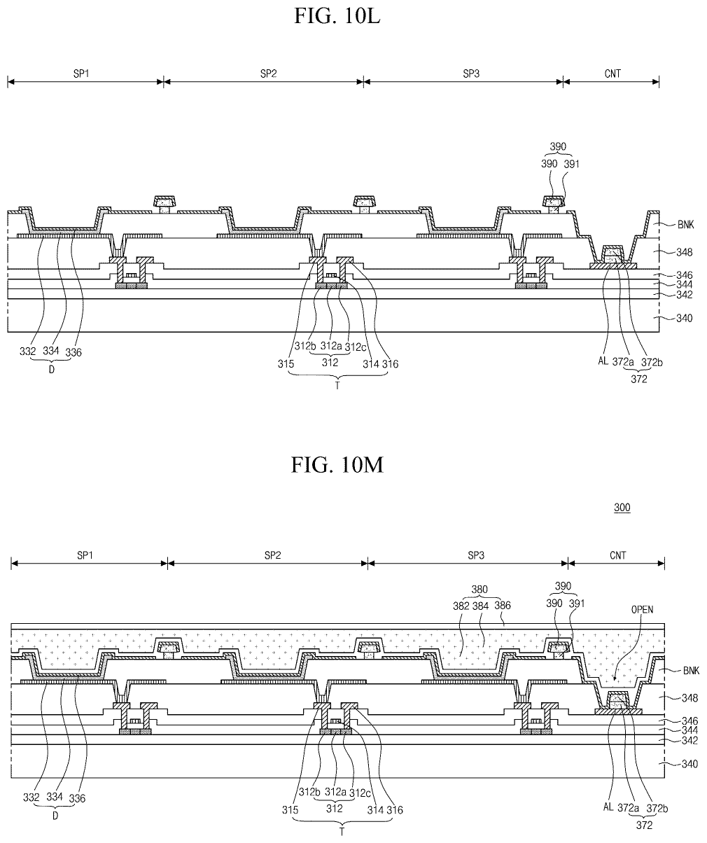

FIGS. 10A-10M are views showing the manufacturing method of the display apparatus 300 according to the present disclosure.

First, as shown in FIG. 10A, the buffer layer 342 is formed over the entire substrate 340 including the first to third sub-pixels SP1, SP2, and SP3 and the contact unit CNT. As will be described in detail later, the contact unit CNT is the area where the second electrode and the auxiliary electrode of the light emitting device are contacted. The contact unit CNT is substantially disposed at one side of each of the first to third sub-pixels SP1, SP2, and SP3, but is shown only at one side of the third sub-pixel SP3 in the figure for convenience of explanation. As an example, the contact unit CNT can be substantially disposed at one or more sides of at least one of the first to third sub-pixels SP1, SP2, and SP3, without being limited thereto. As an example, the contact unit CNT can be not disposed at any side of at least one of the first to third sub-pixels SP1, SP2, and SP3.

The substrate 340 can be made of the hard material such as the glass or the plastic material such as the plastic material can include a polyimide, a polymethylmethacrylate, a polyethylene tereththalate, a Polyethersulfone, and a Polycarbonate.

The buffer layer 342 can be formed of the single layer of SiNx or SiOx, or multiple layers thereof.

Thereafter, the poly-crystalline semiconductor material such as poly-silicon or the oxide semiconductor material such as etching IGZO (Indium-gallium-zinc-oxide), IZO (Indium-zinc-oxide), IGTO (Indium-gallium-tin-oxide), and IGO (Indium-gallium-oxide) is deposed and etched to form the semiconductor layer 312 in each of the first to third sub-pixels SP1, SP2, and SP3. Further, the impurities are doped into the both sides of the semiconductor layer 312 to form the channel region 312a, the source region 312b, and the drain region 312c.

Subsequently, the gate insulating layer is formed 344 by depositing the inorganic material such as SiOx or SiNx, and then the metal such as molybdenum (Mo), aluminum (Al), chromium (Cr), gold (Au), titanium (Ti), nickel (Ni), Neodymium (Nd) and copper (Cu) are deposited by the sputtering method and etched by the wet etching method to form the gate electrode 314. Thereafter, the organic material such as photo acrylic material or the inorganic material such as SiNx or SiOx is deposited on the gate electrode 314 to form the interlayer insulating layer 346, and then the interlayer insulating layer 346 over the source region 312b and the drain region 312c of the semiconductor layer 312 is dry-etched to form the contact holes therein.

Subsequently, the metal such as Cr, Mo, Ta, Cu, Ti, Al, or an Al alloy is deposited by the sputtering method and etched to form the source electrode 315 and the drain electrode 316 which are respectively ohmic-contacted to the source region 312b and the drain region 312c of the semiconductor layer 312 through the contact holes in each of the first to third sub-pixels SP1, SP2, and SP3 and to form auxiliary electrode AL in the contact unit CNT.

Thereafter, the planarization layer 348 is formed by depositing the organic material such as photo-acryl on the source electrode 315 and the drain electrode 316, and then the planarization layer 348 on the drain electrode 316 is dry-etched to form the contact hole.

Thereafter, as shown in FIG. 10B, the metal or the metal oxide is deposited on the planarization layer 348 by the sputtering method and etched by the wet etching method to form the first electrode 332 electrically connected to the drain electrode 316 through the contact hole in each of the sub-pixels SP1, SP2, and SP3, and then at least one material of the inorganic insulating material such as SiNx or SiOx, the organic material such as BCB (BenzoCycloButene), acrylic resin, epoxy resin, phenolic resin, polyamide resin, and polyimide resin, and the photoresist including the black pigment is deposited in edge area on the planarization layer 348 and the first electrode 332, and then dry-etched to form the bank layer 352.

Thereafter, as shown in FIG. 10C, the orthogonal material, specially the fluoropolymer material containing the large amount of fluorine (F) in the functional while carbon-carbon bonds are formed continuously in a chain structure and the photoresist are continuously deposited to form a first orthogonal material layer 374 and a first photoresist layer 376 in the first to third sub-pixels SP1, SP2, and SP3, and the connection unit CNT.

Thereafter, the first photoresist layer 376 is developed using a photomask to form a first photoresist pattern 376a from which the photoresist of the first sub-pixel SP1 is removed. Subsequently, as shown in FIG. 10D, the first orthogonal material layer 374 is etched using the first photoresist pattern 376a as a mask layer to form the first orthogonal material pattern 374a.

As shown in FIG. 10E, the first orthogonal material layer 374 is over-etched and a part of the first orthogonal material layer 374 below the first photoresist pattern 376a is etched, so that the upper first photoresist pattern 376a and the lower first orthogonal material pattern 374a form the undercut shape.

Thereafter, the organic light emitting material is applied over the entire substrate 340 to form an organic material layer 334a. At this time, the organic material layer 334a is formed on the first photoresist pattern 376a and the planarization layer 348 of the first sub-pixel SP1 from which the photoresist has been removed.

Thereafter, when the first orthogonal material pattern 374a is removed by a lift-off method, the first photoresist pattern 376a and the organic material layer 334a on the first orthogonal material pattern 374a are removed, as shown in FIG. 10F, the organic layer 334 is formed only on the first electrode 332 of the first sub-pixel SP1.

As described above, in the manufacturing method according to the present disclosure, the orthogonal material layer 374 is formed and patterned and then removed by the lift-off method to form the organic layer 334, so that the following effects can be obtained.

Since the orthogonal material layer 374 has independent properties from other adjacent layers, such as the planarization layer 348 or the first electrode 332, the orthogonal material layer 374 does not affect the planarization layer 348 or the first electrode 332 at all. Therefore, the chemical damage does not occur between the planarization layer 348 or the first electrode 332 when forming the orthogonal material layer 374, and the planarization layer 348 or the first electrode 332 are not damaged when etching or removing the orthogonal material layer 374. As an example, the auxiliary electrode AL may have the same material as the source electrode 315 and the drain electrode 316, or may have the same material as the gate electrode 314, and/or can be formed in the same process as the source electrode 315 and the drain electrode 316 or the gate electrode 314, without being limited thereto. As an example, the auxiliary electrode AL can be separately formed and may comprise a different material from that of the source electrode 315, the drain electrode 316 or the gate electrode 314.

Subsequently, as shown in FIG. 10G, the process of FIGS. 10C to 10E is repeated for the second and third sub-pixels SP2 and SP3, respectively to form the organic layer 334 is on the first electrode 332 of the second and third sub-pixels SP2 and SP3.

Thereafter, as shown in FIG. 10H, the bank layer BNK and the planarization layer 348 in the contact unit CNT are etched to form the opening OPEN for exposing the auxiliary electrode AL to outside in the bank layer BNK and the planarization layer 348. Subsequently, a second orthogonal material layer 394 and a second photoresist layer 398 are formed in the first to third sub-pixels SP1, SP2, and SP3 and the contact unit CNT by depositing the orthogonal material, specially the fluoropolymer material containing the large amount of fluorine (F) in the functional while carbon-carbon bonds are formed continuously in a chain structure and the photoresist. At this time, the second orthogonal material layer 394 and the second photoresist layer 398 are formed on the organic layer 334 of the first to third sub-pixels SP1, SP2, and SP3, the bank layer (BNK), and the auxiliary electrode AL within the opening OPEN in the contact unit CNT.

Subsequently, the second photoresist layer 398 is patterned by the exposure process to form a second pattern 372b on the auxiliary electrode AL and a disconnection layer 390 on the bank layer BNK, as shown in FIG. 10I.

Thereafter, the second orthogonal material layer 394 is etched using the second pattern 372b and the second disconnection layer 392 as the mask layer to form the first pattern 372a under the second pattern 372a and the first disconnection layer 391 under the second connection layer 392, as shown in FIG. 10J. The first disconnection layer 391 and the second disconnection layer 392 thereon form the disconnection unit 390. At this time, the second orthogonal material layer 394 under the second disconnection layer 392 is over-etched and a part of the second orthogonal material layer 394 under the second disconnection layer 392 is etched, so that the disconnection unit 390 is formed in the undercut shape where the width of the first disconnection layer 391 is smaller than that of the second disconnection layer 392.

The first pattern 372a and the second pattern 372b form the blocking layer 372. At this time, the second orthogonal material layer 394 under the second pattern 372b is over-etched and a part of the second orthogonal material layer 394 under the second pattern 372b is etched, so that the blocking layer 372 is formed in the undercut shape where the width of the first pattern 372a is smaller than that of the second pattern 372b.

In the present disclosure, the blocking layer 372 and the disconnection unit 390 are formed in different layers, but since the blocking layer 372 and the disconnection unit 390 are formed by one process, the manufacturing process can be simplified.

Subsequently, as shown in FIG. 10K, the heat is applied to the substrate 340 and the undercut shape can be changed by heat treatment. For example, the upper layer of the undercut shape is melted and then the difference in width between the upper layer and the lower layer is reduced, so that the widths of the upper and lower layers of the undercut shape become substantially the same, thereby eliminating the undercut shape or discontinuous boundary between the upper layer and the lower layer.

In particular, in the present disclosure, since the heat treatment is performed at the substrate 340 side, the high temperature heat is applied to the blocking layer 372 that is relatively close to the substrate 340, but to the disconnection unit 390 that is relatively far from the substrate 340. Therefore, the blocking layer 372 does not maintain the undercut shape due to heat treatment, while the disconnection unit 390 maintains the undercut shape.

Further, since the width of the blocking layer 372 is small than that of the auxiliary electrode AL disposed below the blocking layer 372, the auxiliary electrode AL extends from both sides of the blocking layer 372 so that a part of the auxiliary electrode AL is exposed to outside through the opening OPEN.

Thereafter, as shown in FIG. 10L, the metal or the metal oxide is deposited over the entire area of the substrate 340 to form the second electrode 336. Since the side surface of the blocking layer 372 formed in the straight shape, not in the undercut shape, the second electrode 336 is formed within the opening OPEN, so that the second electrode 336 is not disconnected in the blocking layer 372 and is formed on both side and the top surfaces of the blocking layer 372 to be extended to the sub-pixels SP1, SP2, and SP3. At this time, since the auxiliary electrode AL is exposed at both sides of the blocking layer 372, the second electrode 336 formed in the opening OPEN is formed on the exposed auxiliary electrode AL. Therefore, the auxiliary electrode AL is electrically connected to the second electrode 336. Meanwhile, since the disconnection unit 390 is formed in the undercut shape, the second electrode 336 is disconnected by the undercut at the side surface of the disconnection unit 390.

Subsequently, as shown in FIG. 10M, the inorganic material is applied to the first to third sub-pixels SP1, SP2, and SP3 and the contact unit CNT to form the first encapsulation layer 382, and the organic material is applied on the first encapsulation layer 382 to form the second encapsulation layer 384. Thereafter, the inorganic material is applied on the second encapsulation layer 384 to form the third encapsulation layer 386, thereby forming the encapsulation layer 380 to seal the display apparatus 300.

As described above, in the method of manufacturing the display apparatus according to the present disclosure, the orthogonal material layer and the photoresist layer are patterned and the organic material is formed thereon, and then organic layer is formed in the sub-pixel by removing the orthogonal material layer, the photoresist layer, and the organic material by the lift-off method. Therefore, compared to the conventional process of depositing a plurality of organic materials using the thin metal mask, the organic layer of uniform thickness can be formed over the large area so that the display apparatus of large area and high resolution can be easily manufactured.

Further, due to the characteristics of the orthogonal material, the damage to the lower layer can be prevented compared to the method of directly etching the organic layer through the photo process.

Meanwhile, in the present disclosure, the orthogonal materials are used when forming the organic layer, the blocking layer, and the disconnection unit, but the present disclosure is not limited to this process. In the present disclosure, the orthogonal material can be used only when forming the blocking layer and the disconnection portion, and the metal mask can be used when forming the organic layer or the organic layer can be directly etched through the photo process.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

What is claimed is:

1. A display apparatus, comprising:
a substrate including a plurality of sub-pixel and a contact unit;
at least one transistor disposed in each sub-pixel;
a light emitting device disposed in each sub-pixel, the light emitting device including a first electrode, an organic layer, and a second electrode;
an auxiliary electrode disposed in the contact unit to supply a voltage to the light emitting device; and
a blocking layer disposed on the auxiliary electrode to block outside moisture,
wherein the blocking layer includes a first pattern made of an orthogonal material and a second pattern on the first pattern,
wherein a width of the blocking layer is smaller than a width of the auxiliary electrode, so that the auxiliary electrode is extended to outside of at least one side of the blocking layer, and the auxiliary electrode is exposed to outside, and
wherein the second electrode is extended to the blocking layer from the sub-pixel so that the second electrode is disposed on both sides of the blocking layer and on an exposed region of the auxiliary electrode.

2. The display apparatus of claim 1, wherein the first pattern is formed of a fluoropolymer material containing a set amount of fluorine (F) while carbon-carbon bonds are formed continuously in a chain structure.

3. The display apparatus of claim 2, wherein the first pattern has hydrophobicity and oleophobicity.

4. The display apparatus of claim 1, wherein the second pattern is formed of a photoresist.

5. The display apparatus of claim 1, further comprising:
a first insulating layer covering the at least one transistor; and
a bank layer disposed between the plurality sub-pixels on the first insulating layer.

6. The display apparatus of claim 5, wherein each of the at least one transistor includes:
a semiconductor layer on the substrate;
a second insulating layer covering the semiconductor layer;
a gate electrode on the second insulating layer;
a third insulating layer covering the gate electrode; and
a source electrode and a drain electrode on the third insulating layer.

7. The display apparatus of claim 6, wherein an opening that the bank layer and the third insulating layer are removed is formed in the contact unit, and the auxiliary electrode is disposed within the opening.

8. The display apparatus of claim 7, wherein the auxiliary electrode is formed of a same material as the source electrode and the drain electrode.

9. The display apparatus of claim 5, further comprising a disconnection unit on the bank layer at one side of the sub-pixel to disconnect the second electrode between the adjacent sub-pixels.

10. The display apparatus of claim 9, wherein the disconnection unit includes:
a first disconnection layer on the bank layer; and
a second disconnection layer on the first disconnect layer,
wherein a width of the first disconnect layer is smaller than a width of the second disconnect layer so that the disconnect unit is formed in an undercut shape.

11. The display apparatus of claim 10, wherein the first disconnection layer is formed of a fluoropolymer material containing a set amount of fluorine (F) while carbon-carbon bonds are formed continuously in a chain structure.

12. The display apparatus of claim 10, wherein the second disconnection layer is formed of a photoresist.

13. The display apparatus of claim 9, wherein the disconnection unit disposed at one side of the sub-pixel include a plurality of disconnection units.

14. A method of manufacturing a display apparatus, the method comprising:
proving a substrate including a plurality of sub-pixels and a contact unit;
forming a transistor in each sub-pixel;
forming an auxiliary electrode in the contact unit;
forming a first electrode and an organic layer in each sub-pixel;
depositing an orthogonal material and a photoresist on entire area of the substrate;
developing the photoresist to form a photoresist pattern on the auxiliary electrode in the contact unit;
over-etching the orthogonal material by the photoresist pattern to form a blocking layer having an undercut shape;
heat-treating the blocking layer; and
forming a second electrode on the entire area of the substrate,
wherein the second electrode is formed on side and upper surfaces of the blocking layer and is electrically connected to the auxiliary electrode extended from both side surfaces of the blocking layer.

15. The method of claim 14, further comprising:
forming an insulating layer covering the transistor;
forming a bank layer between the sub-pixels on the insulating layer; and
etching the insulating layer and the bank layer in the contact unit to form an opening.

16. The method of claim 15, wherein the auxiliary electrode is formed within the opening.

17. The method of claim 15, further comprising a disconnection unit on the bank layer.

18. The method of claim 17, wherein the disconnection unit includes a first connection layer formed of an orthogonal material and a second disconnection layer formed of the photoresist on the first disconnection layer, and
wherein the disconnection unit and the blocking layer are simultaneously formed.

19. The method of claim 14, wherein the forming the organic layer includes:
depositing continuously the orthogonal material and the photoresist on an entire area of the substrate;
removing the photoresist on the first electrode to form the photoresist pattern;
etching the orthogonal material using the photoresist pattern as a mask;
depositing the organic material on the entire area of the substrate; and
forming the organic layer in the plurality of sub-pixels by removing the orthogonal material to remove the photoresist pattern and the organic material on the orthogonal material.

20. The method of claim 19, wherein the etched orthogonal material and the photoresist pattern thereon are formed in the undercut shape.
